(19) United States
(12) Patent Application Publication
(10) Pub. No.: US 2007/0014148 A1
(43) Pub. Date: Jan. 18, 2007

(54) Methods and systems for attaching a magnetic nanowire to an object and apparatuses formed therefrom

(75) Inventors: Otto Z. Zhou, Chapel Hill, NC (US); Guang Yang, Carrboro, NC (US); Jie Tang, Chapel Hill, NC (US); Lu-Chang Qin, Chapel Hill, NC (US)

Correspondence Address: JENKINS, WILSON, TAYLOR & HUNT, P. A., 3100 TOWER BLVD, SUITE 1200, DURHAM, NC, 27707, US

(73) Assignee: The University of North Carolina at Chapel Hill

(21) Appl. No.: 11/377,900

(22) Filed: Mar. 16, 2006

Related U.S. Application Data
(63) Continuation of application No. 10/842,357, filed on May 10, 2004.
(60) Provisional application No. 60/663,128, filed on Mar. 18, 2005.

(51) Int. Cl. G11C 11/00

(52) U.S. Cl. 365/158

(57) ABSTRACT

Methods and systems are provided for attaching one or magnetic nanowires to an object and apparatuses formed therefrom. An electrophoresis method for attaching one or more nanowires to a sharp tip of an object can include including providing one or more magnetic nanowires in a liquid medium. The method can also include positioning a sharp tip of an object in the liquid medium. Further, the method can include applying an electrical field to the liquid medium for attaching the one or more magnetic nanowires to the sharp tip.

### CROSS-REFERENCE TO RELATED APPLICATIONS

This application claims the benefit of U.S. Provisional Patent Application Ser. No. 60/663,128, filed Mar. 18, 2005; and is a continuation application of U.S. patent application Ser. No. 10/842,357, filed May 10, 2004; the disclosures of which are incorporated herein by reference in their entireties.

### GOVERNMENT INTEREST

This invention was made with U.S. Government support under grant number 5-5-58595 awarded by the National Aeronautics and Space Administration (NASA). The U.S. Government has certain rights in the invention.

### TECHNICAL FIELD

The subject matter described herein relates to methods and systems for attaching nanostructures to objects and apparatuses formed therefrom. More particularly, the subject matter described herein relates to methods and systems for attaching one or more magnetic nanowires to an object and apparatuses formed therefrom, and to an electrophoresis method for fabrication of magnetic force microscopy probes using magnetic nanowires.

### BACKGROUND ART

Magnetic force microscopy (MFM) is a non-destructive, experimental technique for investigation of surface magnetic structure of systems such as magnetic storage media. The resolution and sensitivity of MFM depends largely on the geometry and magnetic properties of the MFM's probe. MFM probes are typically fabricated by coating a tip of an atomic force microscope (AFM) cantilever with a layer of hard ferromagnetic materials such as cobalt-based alloy. This process increases the tip radius of the probe. By increasing the probe's tip radius, the spatial resolution of the MFM may be increased to an order of 100 nm. Therefore, it is desirable to reduce the tip radius of MFM probes.

Techniques have been investigated and developed for producing MFM probes with reduced radii. These techniques include the use of either electron beam deposition or focused ion beam milling. In one technique, carbon nanotubes (CNTs) are grown and attached to the apex of a silicon cantilever of a probe. CNTs have nanometer-size diameters and large aspect ratios. The use of CNTs increases the spatial resolution and probing depth of AFMs.

Several different techniques have been developed to produce MFM probes including CNTs. In one technique, a single, multi-wall carbon nanotube (MWNT) capped with a magnetic catalyst particle is mounted onto the apex of a commercial silicon cantilever inside the chamber of a scanning electron microscope (SEM). In another technique, a carbon nanofiber was grown on a tipless Si cantilever using direct chemical vapor deposition (CVD). In the tip-growth CVD process, the encapsulated magnetic particle is positioned at the top of the nanofiber and provides the magnetic force. In yet another technique, MFM probes are produced by sputtering a layer of magnetic film onto the outer surface of a CNT either mounted or catalytically grown on a silicon cantilever. Although the imaging results obtained by using CNT magnetic probes are good, it is desirable to provide probes having improved resolution and probing depth.

In view of the shortcomings of existing magnetic microscopy devices, there exists a need for providing methods and systems for improving the performance and manufacture of these devices as well as the apparatuses produced therefrom.

### SUMMARY

In accordance with this disclosure, novel systems and methods are provided for attaching a magnetic nanowire to an object and apparatuses produced therefrom and for electrophoretic fabrication of magnetic force microscopy probes using magnetic nanowires.

It is an object of the present disclosure therefore to provide novel systems and methods for attaching a magnetic nanowire to an object and apparatuses produced therefrom and to provide a novel electrophoresis method for fabrication of magnetic force microscopy probes using magnetic nanowires in order to improve the manufacture and resolution of devices such as magnetic microscopy devices. This and other objects as may become apparent from the present disclosure are achieved, at least in whole or in part, by the subject matter described herein.

### BRIEF DESCRIPTION OF THE DRAWINGS

Exemplary embodiments of the subject matter will now be explained with reference to the accompanying drawings, of which:

FIG. 1 is a schematic diagram of an exemplary system for attaching one or more magnetic nanowires to a sharp tip of an object according to an embodiment of the subject matter described herein;

FIG. 2 is a flow chart of an exemplary process for attaching one or more magnetic nanowires to a sharp tip of an object according to an embodiment of the subject matter described herein;

FIG. 3 is a TEM image of nickel magnetic nanowires synthesized by an electrodeposition method according to an embodiment of the subject matter described herein;

FIG. 4 is a schematic diagram of an atomic force microscope cantilever having a single magnetic nanowire attached to a tip of the cantilever according to an embodiment of the subject matter described herein;

FIG. 5 is a schematic diagram of an atomic force microscope cantilever having several magnetic nanowires attached to a tip of the cantilever according to an embodiment of the subject matter described herein;

FIG. 6 is an SEM image of exemplary magnetic probes having nickel magnetic nanowires attached according to an embodiment of the subject matter described herein;

FIG. 7 is another SEM image of exemplary magnetic probes having nickel magnetic nanowires attached according to an embodiment of the subject matter described herein;

FIGS. 8, 9, and 10 are SEM images of exemplary magnetic force microscopy probes including nickel magnetic nanowires attached according to an embodiment of the subject matter described herein;

FIG. 11 is a topographic image of a magnetic recording tape obtained using an atomic force microscope having magnetic nanoparticles according to an embodiment of the subject matter described herein;

FIG. 12 is a magnetic image of a magnetic recording tape obtained using an atomic force microscope having magnetic nanoparticles according to an embodiment of the subject matter described herein;

FIG. 13A is a graph showing a height profile of a calibration sample measured using a conventional Si atomic force microscope probe;

FIG. 13B is a graph showing a height profile of a calibration sample measured using an atomic force microscope probe including a nickel magnetic nanowire attached according to the subject matter described herein; and

FIG. 13C is a graph showing a height profile of a calibration sample measured using an atomic force microscope probe including a carbon nanotube attached thereto.

### DETAILED DESCRIPTION

Systems and methods according to the subject matter described herein can be used for attaching one or more magnetic nanowires onto a sharp tip of an object. For example, systems and methods according to the subject matter described herein can be used for attaching one or more magnetic nanowires to a sharp tip of an atomic force microscope.

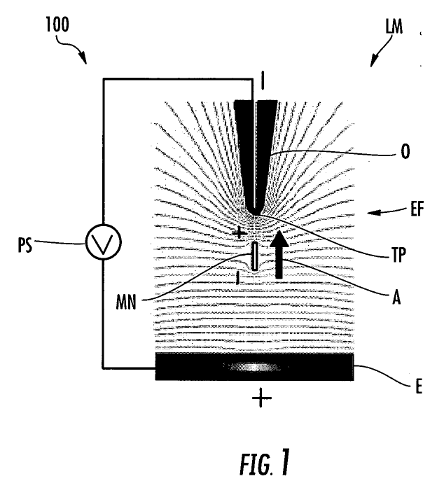

FIG. 1 illustrates a schematic diagram of an exemplary system generally designated 100 for attaching one or more magnetic nanowires MN to a sharp tip TP of an object O according to an embodiment of the subject matter described herein. In this example, object O can be a cantilever of an atomic force microscope. Alternatively, object O can be part of a profilometer, a probe, electron a field emission cathode, a gas discharge tube, a lighting device, a microwave power amplifier, an ion gun, an electron beam lithography device, a high energy accelerator, a free electron laser, and a flat panel display. System 100 can include an electrode E, a power source PS, and a liquid medium generally designated LM. Electrode E, tip TP, and magnetic nanowire MN can be positioned in liquid medium LM. Power source PS can apply a voltage difference between tip TP and electrode E for generating an electrical field (generally designated EF) in liquid medium LM. Electrical field EF can cause magnetic nanowire MN to migrate towards tip TP (in the direction indicated by direction arrow A) and attach to tip TP. In particular, an end of magnetic nanowire MN can attach to tip TP.

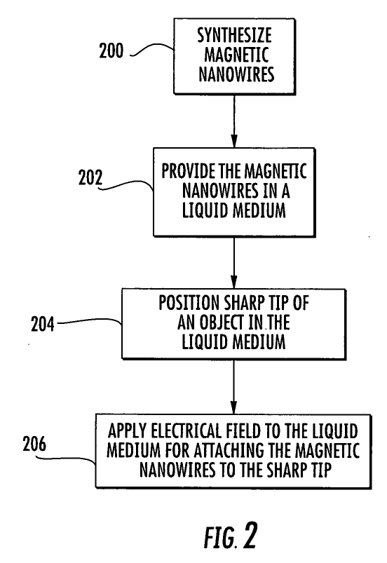

FIG. 2 is a flow chart illustrating an exemplary process for attaching one or more magnetic nanowires to a sharp tip of an object according to an embodiment of the subject matter described herein. In this example, the magnetic nanowires are attached via a positive dielectrophoresis process. Referring to FIG. 2, in block 200, magnetic nanowires can be synthesized or otherwise produced. The magnetic nanowires can be fabricated by electrodeposition using an anodic alumina template with 15-50 nm diameter holes. The electrodeposition can be conducted at room temperature or any other suitable temperature. A water solution containing nickel sulfate and boric acid can be used as an electrolyte. After electrodeposition, the nanowires can be harvested by dissolving the alumina template in phosphoric acid at room temperature or another suitable temperature. The nanowires can then be dispersed in de-ionized water without surfactants, centrifuged, and homogenized in an ultrasonic bath.

A magnetic nanowire can be a nanowire that comprises at least one of the following magnetic materials: nickel (Ni), cobalt (Co), and iron (Fe).

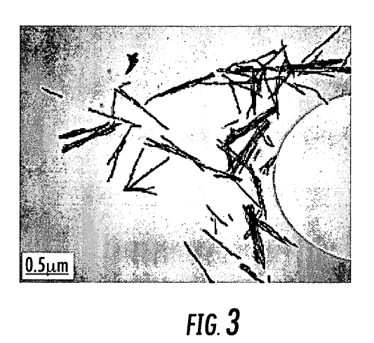

FIG. 3 illustrates a TEM image of nickel magnetic nanowires synthesized by an electrodeposition method according to an embodiment of the subject matter described herein. The lengths of the nanowires vary from about 300 nm to 800 nm in length. The diameters of the nanowires are between about 20 and 40 nm.

The magnetic nanowires can be optionally purified by several techniques including filtration, centrifuge, and chromatography to separate the nanowires from the impurities and to sort the nanowires based on diameter and length. The magnetic nanowires can then be subjected to further processing to shorten the length, such as by chemical etching or by mechanical processes such as ball milling.

According to another embodiment, the purified magnetic nanowires can be shortened by mechanical milling. According to this technique, a sample of the purified magnetic nanowire material is placed inside a suitable container, along with appropriate milling media. The container is then shut and placed within a suitable holder of a ball-milling machine. The time that the sample is milled can vary. An appropriate amount of milling time can be readily determined by inspection of the milled nanowires.

Referring again to FIG. 2, in block 202, the magnetic nanowires can be provided in a liquid medium such as liquid medium LM shown in FIG. 1. The liquid medium can be selected which will permit the formation of a stable suspension of the raw nanowires therein. According to one embodiment, the liquid medium comprises at least one of the following: de-ionized water, methanol, ethanol, alcohol, and dimethylformamide (DMF). Upon adding the nanowires to the liquid medium, the mixture can be subjected to ultrasonic energy or stirring using, for example, a magnetic stirrer bar, in order to facilitate the formation of a stable suspension. The amount of time that the ultrasonic energy is applied can be a suitable time, such as about two hours.

In block 204, a sharp tip of an object can be positioned in the liquid medium. For example, sharp tip TP of object O can be gradually moved from a position outside of liquid medium LM to a position within liquid medium LM as shown in FIG. 1. In one embodiment, electrode E can be a metallic ring positioned in liquid medium LM. Further, electrode E and object O can be mounted on separate translation stages and placed under an optical microscope for observation. Electrode E can be translated to contact liquid medium LM and moved to a position as shown in FIG. 1. Tip TP can be positioned in liquid medium LM for a predetermined period of time. Further, tip TP can be moved towards liquid medium LM until an electrical contact is established between electrode E and tip TP.

In block 206, an electrical field can be applied to the liquid medium for attaching the magnetic nanoparticles to the sharp tip. Power source PS can be controlled to apply a voltage across object O and electrode E for generating an electrical field between object O and electrode E for a predetermined period of time. When the voltage is applied to object O and electrode E, object O can be function as an electrode. Further, the applied voltage can be variably controlled to apply an alternating current (AC) or direct current (DC) to object O and electrode E. In one example, the applied voltage can be about 1-10 V at 2 MHz. The electrical field can cause magnetic nanoparticles to migrate towards sharp tip TP and attach to sharp tip TP. The electrical field applied between object O and electrode E can be about 0.1-1000 V/cm, and a DC of 0.1-200 mA/cm² can be applied for 1 second-1 hour.

Under guidance of an optical microscope, electrode E can be withdrawn from liquid medium LM during application of the electrical field. One end of one or more magnetic nanowires can attach to sharp tip TP. The attached magnetic nanowires can form a magnetic tip with tip TP. The length of the magnetic tip can be controlled by the distance by which object O and electrode E are moved away from one another under the electrical field. Movement of object O and electrode E away from one another under the electrical field can cause the nanowires to straighten and align in the direction of the movement.

In one embodiment, after assembly of one or more magnetic nanowires with an object, a protective material can be applied to the magnetic nanowires and/or the object. One example of the protective material is a layer of polymer coating which can protect the nanowire from damage and increase the mechanical stability of the assembled structure.

According to one embodiment, a “charger” can be added to the liquid medium in order to facilitate electrophoretic deposition. Exemplary chargers include MgCl₂, Y(NO₃)₃, AlCl₃, and sodium hydroxide. Any suitable amount can be utilized. Amounts ranging from less than about 1% up to about 50%, by weight, as measured relative to the amount of nanowire-containing material, can be used. According to another embodiment, the liquid medium can contain less than 1% of the charger.

The direction in which the magnetic nanowires migrate can be controlled through the selection of the charger material. For example, the user of a “negative” charger, such as sodium hydroxide (NaOH) imparts a negative charge to the nanowires, thereby creating a tendency for the nanowires to migrate towards the positive electrode (cathode). Conversely, when a “positive” charger material is used, such as MgCl₂, a positive charge is imparted to the nanowires, thereby creating a tendency for the nanowires to migrate toward the negative electrode (anode).

The adhesion of magnetic nanowires can be improved by incorporation of adhesion promoting materials such as binders. These materials can be introduced by, for example, one of the following processes: co-deposition of the nanowires and particles of adhesion promoting materials, sequential deposition, pre-deposition of a layer of adhesion promoting materials, and the like. In one example, a magnetic nanowire can be annealed for attaching to a sharp tip of an object. The annealing can occur at a suitable temperature, such as 100° C. to 600° C. Further, a magnetic nanowire can be annealed for a suitable time period, such as approximately 1 to 60 minutes. Annealing can occur at a pressure of about 10⁻⁶ Torr or another suitable vacuum pressure.

In one embodiment, binders such as polymer binders can be added to a suspension of magnetic nanowire material which is then either stirred or sonicated to obtain a uniform suspension. Suitable polymer binders include poly(vinyl butyral-co vinyl alcohol-co-vinyl acetate) and poly(vinylidene fluoride). Suitable chargers are chosen such that under the applied electrical field, either DC or AC, the binder and the nanostructures would migrate to the same electrodes to form a coating with an intimate mixing of the nanostructures and the binder.

The binders or adhesion promoting materials can be added in any suitable amount. Amounts ranging from 0.1-20% by weight, measured relative to the amount of nanostructure-containing material can be provided.

FIG. 4 illustrates a schematic diagram of an atomic force microscope cantilever C having a single magnetic nanowire MN attached to a tip TP of cantilever C according to an embodiment of the subject matter described herein. Referring to FIG. 4, an end of magnetic nanowire MN is attached to tip TP of cantilever C. Further, nanowire MN can be substantially straight and aligned with a cone axis of cantilever C. The direction of alignment of nanowire MN is the same as the direction of the electrical field applied during attachment. A tip 400 of the assembly of magnetic nanowire MN and cantilever C can have a single magnetic domain.

FIG. 5 illustrates a schematic diagram of an atomic force microscope cantilever C having several magnetic nanowires MN1, MN2, and MN3 attached to a tip TP of cantilever C according to an embodiment of the subject matter described herein. Referring to FIG. 5, ends of magnetic nanowires MN1 and MN2 can be attached to or near a tip of cantilever C by an attachment process described herein. Further, magnetic nanowire MN3 can be attached to magnetic nanowires MN1 and MN2 by an attachment process described herein. Magnetic nanowires MN1, MN2, and MN3 can be substantially aligned with a cone axis of cantilever C and with one another. A tip 500 of the assembly of magnetic nanowires MN1, MN2, and MN3 and cantilever C can have a single magnetic domain.

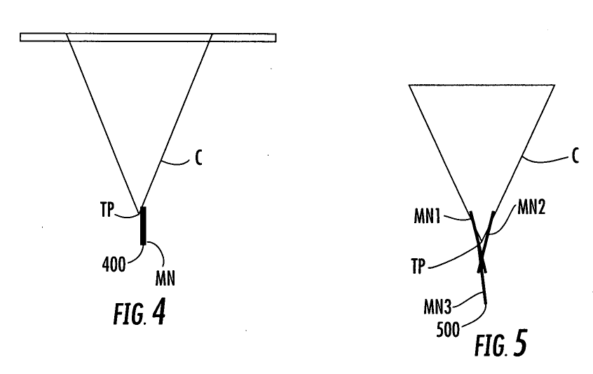

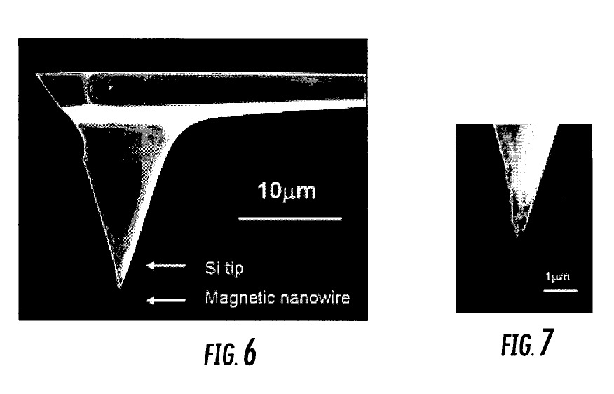

FIGS. 6 and 7 are SEM images of exemplary magnetic probes having nickel magnetic nanowires attached according to an embodiment of the subject matter described herein. The probe tip is about 2 μm in length and about 30 nm in diameter at its tip. A bundle of magnetic nanowires are attached to the tip of the probe. A single magnetic nanowire protrudes from the bundle and, provides the small tip diameter. Probes formed using cobalt magnetic nanowires have a similar structure and morphology as probes formed using nickel magnetic nanowires.

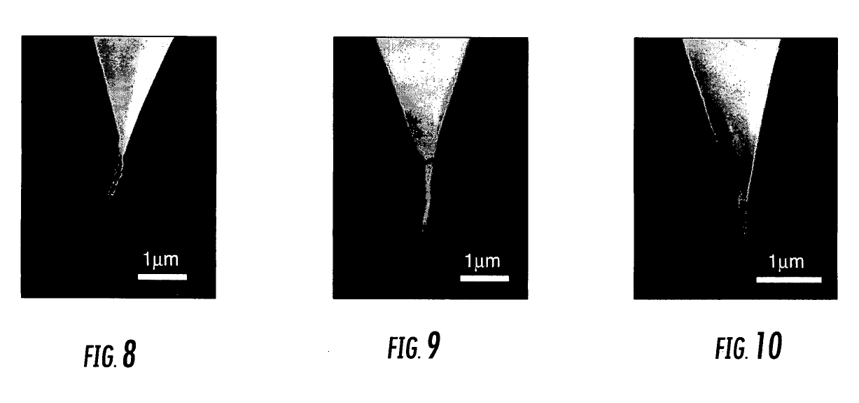

FIGS. 8, 9, and 10 are SEM images of exemplary magnetic force microscopy probes including nickel magnetic nanowires attached according to an embodiment of the subject matter described herein. The probes include nanowires of different length and morphology. These probes were annealed under 10⁻⁶ Torr vacuum. During experimentation, it was found that the Ni and the Co nanowires recrystallized into large particles when annealed at temperatures above 800° C. Annealing at 750° C. for about one hour can improve adhesion between the individual nanowires forming the tip, although conglomeration of the metal coating on the Si cantilever was observed after annealing.

By varying the conditions such as concentration and dispersion of magnetic nanowires in a liquid medium, the electrical field strength, and the rate at which an object tip is withdrawn from a liquid medium surface, the spacing and the alignment of magnetic nanowires on the object tip can be altered.

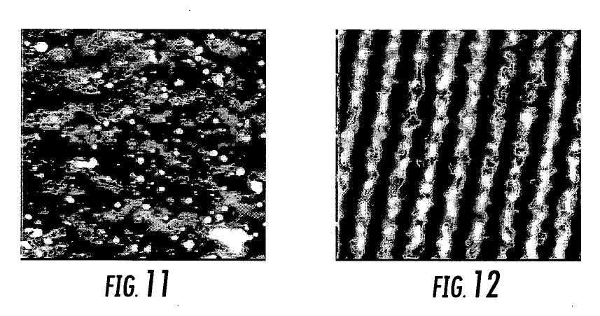

FIGS. 11 and 12 are a topographic image and a magnetic image, respectively, of a magnetic recording tape obtained using an atomic force microscope having magnetic nanoparticles according to an embodiment of the subject matter described herein. The microscope was magnetized prior to imaging. The microscope probe with nickel nanowires used for imaging included a tip diameter of about 30 nm over a 4 μm×4 μm area. The images demonstrate that improved spatial resolution can be obtained by attachment of magnetic nanowires according to the systems and methods described herein.

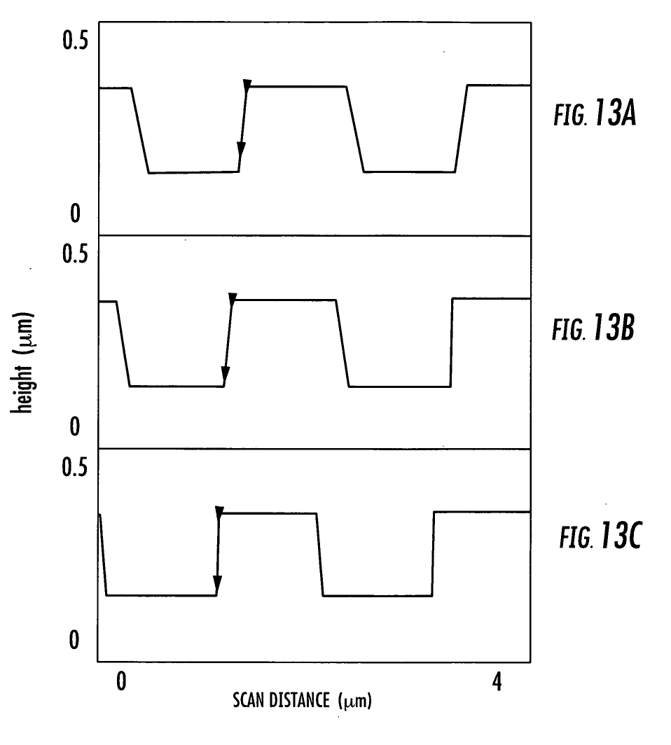

FIGS. 13A-13C illustrate graphs showing height profiles of a calibration sample measured using different atomic force microscope probes. FIG. 13A shows the measured height profile provided by a conventional Si atomic force microscope probe. FIG. 13B shows the measured height profile provided by an atomic force microscope probe including a nickel magnetic nanowire attached according to the subject matter described herein. FIG. 13C shows the measured height profile provided by an atomic force microscope probe including a carbon nanotube attached thereto. The sidewall angles measured in FIGS. 13A-13C are 68°, 78°, and 84°, respectively. The actual sidewall angle is 90°.

The systems and methods according to the subject matter described herein can be used for incorporating magnetic nanowires into profilometers and probes for electron microscopes, electron field emission cathodes for devices such as x-ray generating devices, gas discharge tubes, lighting devices, microwave power amplifiers, ion guns, electron beam lithography devices, high energy accelerators, free electron lasers, and flat panel displays. For example, the methods described herein can be used to deposit a single or a bundle of nanowires selectively onto a sharp tip. The sharp tip can be, for example, the tip used for microscopes including scanning tunneling microscopes (STMs), magnetic force microscopes (MFMs), and chemical force microscopes (CFMs).

Further, the system and methods according to the subject matter described herein can be used for attaching any suitable conductive nanoparticle to a sharp tip. For example, the systems and methods can be used for attaching a nanotube, such as a carbon nanotube, including a magnetic material to a sharp tip. A nanotube structure having a composition of BₓC_{y}N, (B=boron, C=carbon, and N=nitrogen), or nanotube or concentric fullerene structures with a composition MS₂ (M=tungsten, molybdenum, or vanadium oxide) can be utilized.

It will be understood that various details of the subject matter described herein may be changed without departing from the scope of the subject matter described herein. Furthermore, the foregoing description is for the purpose of illustration only, and not for the purpose of limitation.

What is claimed is:

1. An electrophoresis method for attaching a magnetic nanowire to a sharp tip of an object, the method comprising:
(a) providing a magnetic nanowire in a liquid medium;
(b) positioning a sharp tip of an object in the liquid medium; and
(c) applying an electrical field to the liquid medium for attaching the magnetic nanowire to the sharp tip.

2. The method of claim 1 wherein the magnetic nanowire comprises magnetic material selected from the group consisting of nickel, cobalt, and iron.

3. The method of claim 1 wherein the magnetic nanowire comprises a transition metal.

4. The method of claim 1 wherein the liquid medium comprises material selected from the group consisting of water and alcohol.

5. The method of claim 1 wherein providing the magnetic nanowire comprises producing the magnetic nanowire with a predetermined diameter and length.

6. The method of claim 1 wherein the sharp tip is an atomic force microscope probe.

7. The method of claim 1 wherein positioning a sharp tip of an object in the liquid medium comprises positioning the sharp tip of the object in the liquid medium for a predetermined period of time.

8. The method of claim 1 wherein positioning a sharp tip of an object in the liquid medium comprises moving the sharp tip of the object toward the liquid medium until an electrical contact is established between an electrode and the tip.

9. The method of claim 1 wherein applying an electrical field to the liquid medium comprises positioning an electrode in the liquid medium and applying a voltage between the object and the electrode.

10. The method of claim 9 wherein applying a voltage between the sharp tip and the electrode comprises applying an AC voltage between about 1-20 volts.

11. The method of claim 9 wherein applying a voltage between the sharp tip and the electrode comprises controlling the voltage to apply an alternating current to the object and the electrode.

12. The method of claim 1 comprising adding charger to the liquid medium.

13. The method of claim 1 comprising adding adhesion material to the liquid medium.

14. The method of claim 1 comprising removing the sharp tip from the liquid medium during application of the electrical field.

15. The method of claim 1 wherein providing a magnetic nanowire in a liquid medium comprises providing a plurality of magnetic nanowires in the liquid medium, and wherein applying an electrical field to the liquid medium comprises applying an electrical field to the liquid medium for attaching the plurality of magnetic nanowires to the sharp tip.

16. A device comprising a sharp tip comprising a magnetic nanowire attached thereto according to the method of claim 1.

17. A dielectrophoresis method for fabricating magnetic force microscope probes, wherein the method comprises:
(a) dispersing one or more pre-formed magnetic nanowires in a liquid medium;
(b) positioning a sharp tip to contact the liquid medium;
(c) establishing an electrical field between the sharp tip and a counter electrode that is in contact with the liquid medium; wherein the electrical field aligns the one or more magnetic nanowires in a direction of the electrical field and attracts the one or more magnetic nanowires toward the sharp tip; and
(d) separating the sharp tip and the liquid medium.

18. A system for attaching one or more magnetic nanowires to a sharp tip of an object, the system comprising:
(a) a liquid medium including one or more magnetic nanowires and a sharp tip of an object;
(b) an electrode positioned in the liquid medium; and
(c) a power source operable to apply an electrical field in the liquid medium between the sharp tip of the object and the electrode for attaching the one or more magnetic nanowires to the sharp tip.

19. The system of claim 18 wherein the one or more magnetic nanowires comprises magnetic material selected from the group consisting of nickel, cobalt, and iron.

20. The system of claim 18 wherein the liquid medium comprises material selected from the group consisting of water and alcohol.

21. The system of claim 18 wherein the liquid medium includes a charger.

22. The system of claim 18 wherein the liquid medium comprises an adhesion material.

23. The system of claim 18 wherein the power source is operable to apply a voltage between the object and the electrode.

24. The system of claim 23 wherein the applied voltage is between about 1-20 volts.

25. The system of claim 18 wherein the power source is operable to apply an alternating current to the object and the electrode.

26. The system of claim 18 wherein the power source is operable to apply a direct current to the object and the electrode.

27. The system of claim 18 wherein the liquid medium includes a plurality of magnetic nanowires, and wherein the power source is operable to apply an electrical field in the liquid medium between the sharp tip of the object and the electrode for attaching the plurality of magnetic nanowires to the sharp tip.

28. An atomic force microscope apparatus comprising:
(a) an object including a sharp tip; and
(b) at least one magnetic nanowire including an end attached to the sharp tip.

29. The atomic force microscope apparatus of claim 28 wherein the magnetic nanowire comprises magnetic material selected from the group consisting of nickel, cobalt, and iron.

30. The atomic force microscope apparatus of claim 29 wherein the end of the magnetic nanowire is attached to the tip with an adhesion material.
